(19) United States
(12) Patent Application Publication
(10) Pub. No.: US 2023/0333814 A1
(43) Pub. Date: Oct. 19, 2023

(54) COMPUTE-IN MEMORY (CIM) DEVICE AND COMPUTING METHOD THEREOF

(71) Applicant: Taiwan Semiconductor Manufacturing Company, Ltd., Hsinchu (TW)

(72) Inventors: Jui-Che TSAI, Tainan City (TW); Po-Hao LEE, Hsinchu City (TW); Perng-Fei YUH, Hsinchu City (TW); Yih WANG, Hsinchu City (TW)

(21) Appl. No.: 17/720,935

(22) Filed: Apr. 14, 2022

(51) Int. Cl. G06F 7/504

(52) U.S. Cl. CPC G06F 7/504; G11C 7/22

(57) ABSTRACT

Compute-in memory (CIM) devices are provided. A memory is configured to multiply input data by a weight to obtain an adder input. An addition circuit is configured to receive the adder input to provide an adder output, and includes a pre-computation circuit and an adder tree. The pre-computation circuit includes a parameter extractor and a parameter identification circuit. The parameter extractor is configured to extract an input parameter from the adder input. The parameter identification circuit is configured to provide a pre-computation result corresponding to the input parameter as the adder output when determining that the input parameter is present in a parameter table, and provide a control signal when determining that the input parameter is not present in the parameter table. The adder tree is configured to provide the adder output according to the adder input in response to the control signal.

### BACKGROUND

With the maturity of artificial intelligence technology, various applications with artificial intelligence (AI) computing capabilities have flourished. In order to improve neural networks that perform artificial intelligence computing, a concept of compute-in-memory (CIM) is proposed.

Compute-in-memory (CIM) or in-memory computing (IMC) systems store information in the Static Random Access Memory (SRAM) of electronic devices and perform calculations at the memory cell level, rather than moving large quantities of data between the SRAM and the data storage for each step in the computation. Because stored data is accessed much more quickly when it is stored in SRAM, CIM allows data to be analyzed in real time, enabling faster reporting and decision-making in business and machine-learning applications. Efforts are ongoing to improve the performance of compute-in-memory systems.

### BRIEF DESCRIPTION OF THE DRAWINGS

Aspects of the present disclosure are best understood from the following detailed description when read with the accompanying figures. It should be noted that, in accordance with the standard practice in the industry, various nodes are not drawn to scale. In fact, the dimensions of the various nodes may be arbitrarily increased or reduced for clarity of discussion.

FIG. 1 shows a compute-in memory (CIM) device, in accordance with some embodiments of the disclosure.

FIG. 2 shows an example of the memory of FIG. 1, in accordance with some embodiments of the disclosure.

FIG. 3 shows the adder tree of FIG. 1, in accordance with some embodiments of the disclosure.

FIG. 4 shows a CIM device, in accordance with some embodiments of the disclosure.

FIG. 5 shows a CIM device, in accordance with some embodiments of the disclosure.

FIG. 6 shows a CIM device, in accordance with some embodiments of the disclosure.

FIG. 7 shows a CIM device, in accordance with some embodiments of the disclosure.

FIG. 8 shows a CIM device, in accordance with some embodiments of the disclosure.

FIG. 9 shows a computing method, in accordance with some embodiments of the disclosure.

### DETAILED DESCRIPTION

The following disclosure provides many different embodiments, or examples, for implementing different nodes of the subject matter provided. Specific examples of components and arrangements are described below to simplify the present disclosure. These are, of course, merely examples and are not intended to be limiting. In some embodiments, the formation of a first node over or on a second node in the description that follows may include embodiments in which the first and the second nodes are formed in direct contact, and may also include embodiments in which additional nodes may be formed between the first and the second nodes, such that the first and the second nodes may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and/or after a disclosed method, and some of the operations described can be replaced or eliminated for other embodiments of the method.

Artificial intelligence (AI) networks, such as deep neural networks (DNN), are often required to perform a matrix multiplication. Matrix data is transmitted (moved) from a memory to a computing circuit for the matrix multiplication. In the computing process of the AI network, the movement of a large amount of data will consume time and energy. Compute-in-memory (CIM) technology can reduce the number of data movements by using the memory to perform multiply-accumulate (MAC) operations.

In some embodiments, CIM technology is to use memory cells as nodes in the neural network, write data into the memory cells, change equivalent resistances or transduction values of the memory cells as weights, and then provide input signals to the memory cells so that the memory cells can perform multiplication and addition (or convolution operation) on the input signals to generate a computation result. The operation in memory may be used to greatly reduce a circuit area and improve an execution efficiency of the neural network.

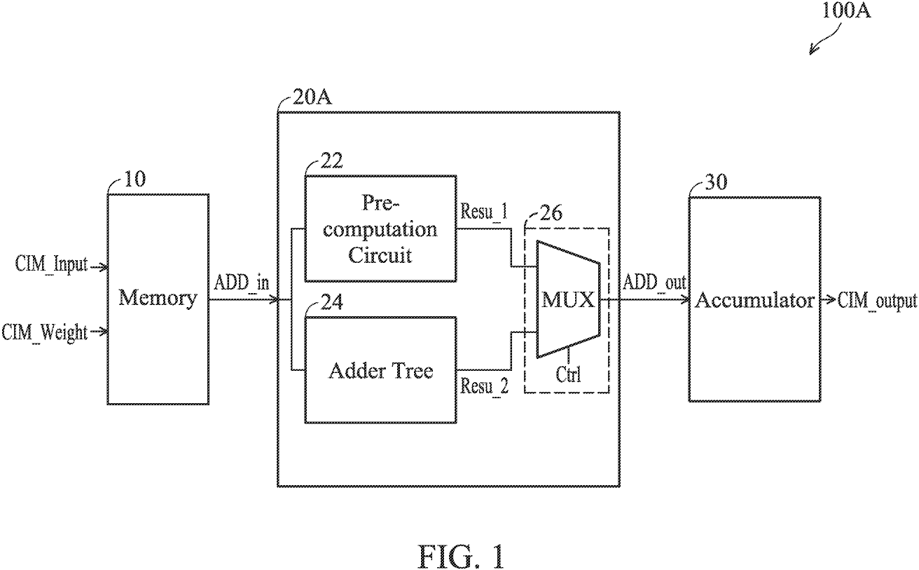

FIG. 1 shows a compute-in memory (CIM) device 100A, in accordance with some embodiments of the disclosure. The CIM device 100A may be an integrated circuit (IC). The CIM device 100A includes a memory 10, an addition circuit 20A and an accumulator 30. The memory 10 may be a static random access memory (SRAM), a dynamic random access memory (DRAM), or other types of memories. The memory 10 has a memory array formed by multiple memory cells arranged in rows and columns of the memory array.

In some embodiments, the memory 10 can operate in two modes: a normal mode and a compute mode. In the normal mode, the memory 10 is typically configured for data storage. Furthermore, in the compute mode, the memory 10 is configured for data computation of the input data CIM_Input and the weight CIM_Weight. For example, each memory cell is capable of receiving one bit of the input data CIM_Input and one bit of the weight CIM_Weight and then generating one bit of data ADD _in that is the arithmetic product of the input data CIM_Input and the weight CIM_Weight, i.e., ADD_in= CIM_Input × CIM_Weight. In other words, the memory 10 is configured to function as a multiplier in the compute mode. In some embodiments, the bit number of the input data CIM_Input is different from the bit number of the weight CIM_Weight. In some embodiments, the bit number of the input data CIM_Input is greater than the bit number of the weight CIM_Weight.

In some embodiments, the CIM device may be a digital type of CIM device that uses a large amount of adders. Compared with an analog type of CIM device, the digital type of CIM device has better signal-to-noise (SNR) and process, voltage and temperature (PVT)/device variation which can keep signal magnitude without accuracy loss and excellent technology scalability.

The addition circuit 20A includes a pre-computation circuit 22, an adder tree 24 and a selection unit 26. For the addition circuit 20A, the data ADD_in from the memory 10 can be used as the input data for the addition operation, hereinafter referred to as the adder input ADD_in for the addition circuit 20A. The pre-computation circuit 22 is configured to receive the adder input ADD_in and provide a pre-computation (or precomputed) result Resu_1 according to the adder input ADD_in. Furthermore, the adder tree 24 is configured to perform the addition operations on the adder input ADD_in to obtain the computed result Resu_2. In response to the control signal Ctrl, the selection unit 26 is configured to selectively provide the pre-computation result Resu_1 or the computed result Resu_2 as the adder output ADD_out. In some embodiments, the selection unit 26 may be a multiplexer (MUX).

The addition circuit 20A is configured to provide the control signal Ctrl according to information of the adder input ADD_in. According to the information of the adder input ADD_in, the pre-computation circuit 22 is configured to determine whether a computation result of the adder input ADD_in is pre-stored in the addition circuit 20. When the computation result of the adder input ADD_in is pre-stored in the addition circuit 20A, the pre-computation circuit 22 is configured to provide the pre-computation result Resu_1 corresponding to the adder input ADD_in to the selection unit 26, so as to provide the pre-computation result Resu_1 as the adder output ADD_out through the selection unit 26. In other words, the pre-computation circuit 22 is capable of providing a fast path for the addition operation of the adder input ADD_in. In some embodiments, once detecting that the computation result of the adder input ADD_in is pre-stored in the addition circuit 20A, the addition circuit 20A is configured to disable (or bypass) the adder tree 24 or stop the addition operation of the adder tree 24, so that no computed result Resu_2 is completed by the adder tree 24. Conversely, when the computation result of the adder input ADD_in is not pre-stored in the addition circuit 20A, no pre-computation result Resu_1 is provided by the pre-computation circuit 22. Simultaneously, the adder tree 24 is configured to perform the addition operations on the adder input ADD_in, so as to provide the computed result Resu_2 as the adder output ADD_out through the selection unit 26. In other words, the adder tree 24 is capable of providing a normal path for the addition operations of the adder input ADD_in. In some embodiments, one or more switching units are used in the normal path so as to gate the operation of the adder tree 24. The switching unit may be a header, a footer, a transmission gate or a logic cell (e.g., NAND or NOR gate).

The accumulator 30 is configured to perform an accumulative adding calculation for the adder output ADD_out, so as to provide the accumulated output data CIM_output. Thus, the CIM device 100A is configured to obtain the accumulated output data CIM_output according to the input data CIM_Input and the weight CIM_Weight. Furthermore, when the adder output ADD_out is obtained according to the pre-computation result Resu_1 through the selection unit 26, the power consumption of the CIM device 100A is decreased because the adder tree 24 in the normal path is disabled (or powered down).

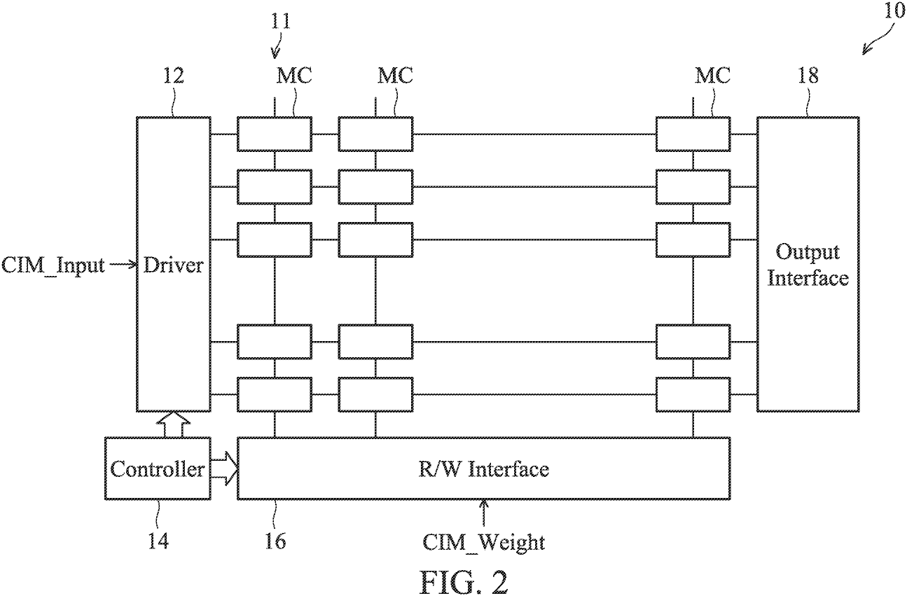

FIG. 2 shows an example of the memory 10 of FIG. 1, in accordance with some embodiments of the disclosure. The memory 10 includes a memory array 11 formed by multiple memory cells MC, and the memory cells MC are arranged in rows and columns in the memory array 11. The memory 10 further includes a driver 12, a controller 14, a read/write (R/W) interface and an output interface 18.

The controller 14 is configured to control the driver 12, the R/W interface 16 and the output interface 18 to access the memory array 11 in the normal mode and the compute mode. In some embodiments, the driver 12 is a word line (WL) driver in the normal mode and an input activation driver in the compute mode. In the normal mode, the controller 14 is configured to write data into the memory array 11 and/or read data from the memory array 11. In the compute mode, the controller 14 is configured to control the driver 12 and the R/W interface 16 to provide the input data CIM_Input and the weight CIM_Weight so as to perform data computation. It should be noted that any memory that can perform data computation can be used in the embodiments of the disclosure.

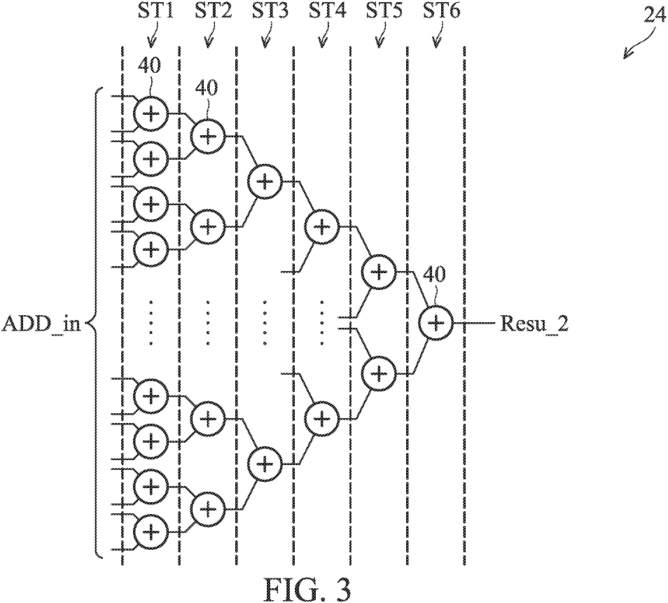

FIG. 3 shows the adder tree 24 of FIG. 1, in accordance with some embodiments of the disclosure. In FIG. 3, the adder tree 24 includes the adders 40 interconnected in a tree-like configuration. In some embodiments, the tree-like configuration is divided into the stages ST1 through ST6. In such embodiment, the stage ST1 is the input stage and the stage ST6 is the output stage.

The adder tree 24 is configured to perform summation on the adder input ADD_in to generate the computed result Resu_2. In FIG. 3, the adders 40 in the stage ST1 are configured to perform the addition operations on the adder input ADD_in. The adders 40 in the stage ST2 are configured to perform the addition operations on the outputs of the adders 40 in the stage ST1. The adders 40 in the stage ST3 are configured to perform the addition operations on the outputs of the adders 40 in the stage ST2, and so on. Finally, the adder 40 in the stage ST6 is configured to perform the addition operations on the outputs of the adders 40 in the stage ST5, so as to provide the computed result Resu_2. In FIG. 3, the number of adders 40 and the stages of the tree-like configuration are used as an example, and not to limit the disclosure. The stage number of the adder tree 24 is proportion to the number of the memory cells MC in the memory array 11 of FIG. 2. Moreover, when the number of the adders 40 is increased, the power consumption of the adder tree 24 is increased.

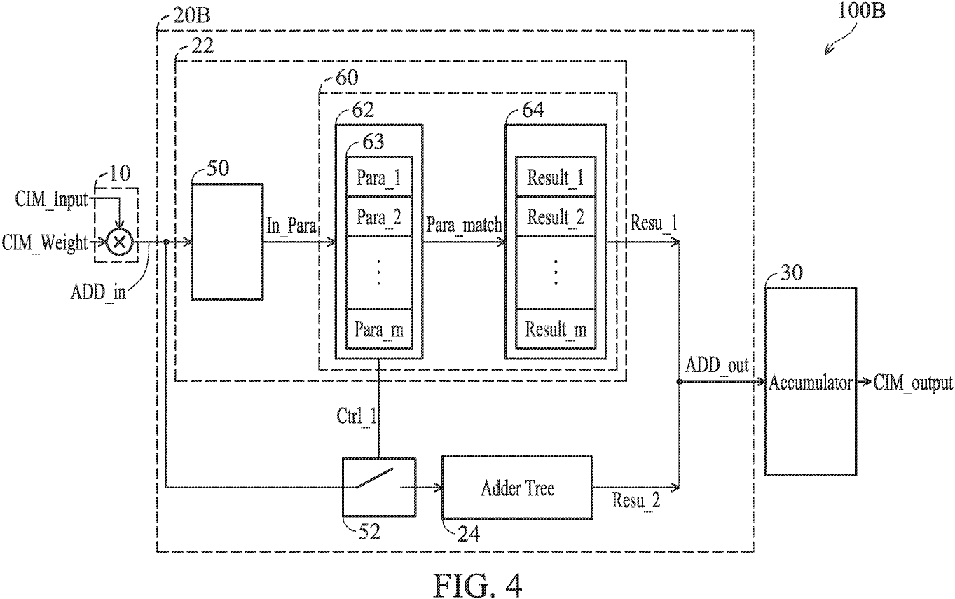

FIG. 4 shows a CIM device 100B, in accordance with some embodiments of the disclosure. The CIM device 100B may be an IC. The CIM device 100B includes the memory 10, an addition circuit 20B and the accumulator 30. The addition circuit 20B includes the pre-computation circuit 22, a switching unit 52 and the adder tree 24. The switch unit 52 is coupled between the adder tree 24 and the memory 10. As described above, the pre-computation circuit 22 is capable of providing a fast path for the addition operation of the adder input ADD_in. Furthermore, when the switching unit 52 is turned on by the control signal Ctrl_1, the adder tree 24 is capable of providing a normal path for the addition operation of the adder input ADD_in.

The pre-computation circuit 22 includes a parameter extractor 50 and a parameter identification circuit 60. The parameter extractor 50 is configured to extract (or obtain) an input parameter In_Para from the adder input ADD_in. In some embodiments, the parameter extractor 50 is configured to count the number of “1” in binary representation of the adder input ADD_in to obtain the input parameter In_Para. In some embodiments, the parameter extractor 50 is configured to perform a specific function (e.g., the parity function or the remainder function) on the adder input ADD_in to obtain the input parameter In_Para.

The parameter identification circuit 60 includes a parameter comparing circuit 62 and a storage device 64. The parameter comparing circuit 60 is configured to compare the input parameter In_Para with the pre-stored parameters Para_1 through Para_m in a parameter table 63. If the input parameter In_Para is identified according to the parameter table 63, e.g., the input parameter In_Para is equal to one of the pre-stored parameters Para_1 through Para_m in the parameter table 63, the parameter comparing circuit 62 is configured to provide a match signal Para_match to the storage device 64. Moreover, the match signal Para_match is provided to notify the storage device 64 that which one of the pre-stored parameters Para_1 through Para_m in the parameter table 63 matches the input parameter In_Para.In some embodiments, the pre-stored parameters Para_1 through Para_m are set in corresponding registers, and a comparator (or XOR gates) is used to compare the input parameter In_Para with the pre-stored parameters Para_1 through Para_m.

Multiple pre-stored results Result_1 through Result_m are stored in the storage device 64. The pre-stored results Result_1 through Result_m correspond to the pre-stored parameters Para_1 through Para_m in the parameter table 63, respectively. For example, the pre-stored result Result_1 corresponds to the pre-stored parameter Para_1, the pre-stored result Result_2 corresponds to the pre-stored parameter Para_2, and so on. In some embodiments, the storage device 64 is a memory.

In response to the match signal Para_match which indicates the matching pre-stored parameter, the storage device 64 is configured to provide the pre-stored result corresponding to the matching pre-stored parameter as the pre-computation result Resu_1. For example, when the input parameter In_Para is equal to the pre-stored parameter Para_2 in the parameter table 63, the parameter comparing circuit 62 is configured to provide the match signal Para_match indicating the pre-stored parameter Para_2 to the storage device 64. Next, the storage device 64 is configured to provide the pre-stored result Result_2 corresponding to the pre-stored parameter Para_2 as the pre-computation result Resu_1.

The pre-computation circuit 22 is configured to provide a fast path for the addition operations of common cases (frequent cases) or worst cases that may increase power consumption in the adder tree 24. For example, one kind of worst cases is that the inputs of all adders 40 in the input stage (e.g., the stage ST1 in FIG. 3) are changed, e.g., form all “0” to all “1” or form all “1” to all “0”, thus inducing toggling in all adders 40 of the adder tree 24. Therefore, the power consumption of the adder tree 24 is increased in the such worst case. In some embodiments, the common cases include the operations that are commonly used in AI, machine learning and CIM applications. In other word, according to the input parameter In_Para from the parameter extractor 50, the parameter comparing circuit 62 is configured to determine whether the adder input ADD_in conforms to the common cases (frequent cases) or worst cases by comparing the input parameter In_Para with the parameter table 63. The parameter table 63 is used to record the worst-case and common-case input parameters. If the input parameter In_Para matches one of the worst-case or common-case input parameters, the addition circuit 20B can bypass (or disable) the adder tree 24 and provide the calculation result of the worst/common case pre-stored in the storage device 64.

In some embodiments, the switching unit 52 is initially turned on by the control signal Ctrl_1. If the input parameter In_Para is identified according to the parameter table 63, e.g., the input parameter In_Para is equal to one of the pre-stored parameters Para_1 through Para_m in the parameter table 63, the parameter comparing circuit 62 is configured to provide the control signal Ctrl_1 to turn off the switching unit 52. Thus, no adder input ADD_in is input to the adder tree 24, and no adder 40 in the stages ST1 through ST6 in FIG. 3 is toggling, i.e., no signal is changed in the inputs of the adder 40. Therefore, no computed result Resu_2 is provided by the adder tree 24, and the addition circuit 20B is configured to provide the pre-computation result Resu_1 as the adder output ADD_out. In such embodiment, the power consumption of the CIM device 100B is decreased because the switching unit 52 in the normal path is turned off and the adder tree 24 cannot receive the adder input ADD_in. Conversely, if the input parameter In_Para is not identified, e.g., the input parameter In_Para is different from the pre-stored parameters Para_1 through Para_m in the parameter table 63, the parameter comparing circuit 62 does not provide the match signal Para_match to the storage device 64. Simultaneously, the parameter comparing circuit 62 is configured to provide the control signal Ctrl_1 to continue to turn on the switching unit 52. Thus, the adder tree 24 is configured to receive the adder input ADD_in and perform the addition operation on the adder input ADD_in to obtain the computed result Resu_2, and then the addition circuit 20B is configured to provide the computed result Resu_2 as the adder output ADD_out.

In some embodiments, the switching unit 52 is initially turned off by the control signal Ctrl_1. If the input parameter In_Para is identified according to the parameter table 63, e.g., the input parameter In_Para is equal to one of the pre-stored parameters Para_1 through Para_m in the parameter table 63, the parameter comparing circuit 62 is configured to provide the control signal Ctrl_1 to continue to turn off the switching unit 52. Thus, no computed result Resu_2 is provided by the adder tree 24, and the addition circuit 20B is configured to provide the pre-computation result Resu_1 as the adder output ADD_out. In such embodiment, the power consumption of the CIM device 100B is decreased because the switching unit 52 in the normal path is turned off and the adder tree 24 cannot receive the adder input ADD_in. Conversely, if the input parameter In Para is not identified, e.g., the input parameter In Para is different from the pre-stored parameters Para_1 through Para_m in the parameter table 63, the parameter comparing circuit 62 does not provide the match signal Para_match to the storage device 64. Simultaneously, the parameter comparing circuit 62 is configured to provide the control signal Ctrl_1 to turn on the switching unit 52. Thus, the adder input ADD_in is provided to the adder tree 24 through the switching unit 52. Next, the adder tree 24 is configured to perform the addition operations on the adder input ADD_in to obtain the computed result Resu_2, and then the addition circuit 20B is configured to provide the computed result Resu_2 as the adder output ADD_out.

In some embodiments, if the input parameter In Para is not identified, e.g., the input parameter In Para is different from the pre-stored parameters Para_1 through Para_m in the parameter table 63, the parameter comparing circuit 62 further provide a control signal (not shown) to control the storage device 64 to enter a power-save mode. For example, if the storage device 64 is a non-volatile memory, the parameter comparing circuit 62 may control the storage device 64 to enter a power down mode. If the storage device 64 is a volatile memory, the parameter comparing circuit 62 may control the storage device 64 to enter a deep-sleep mode.

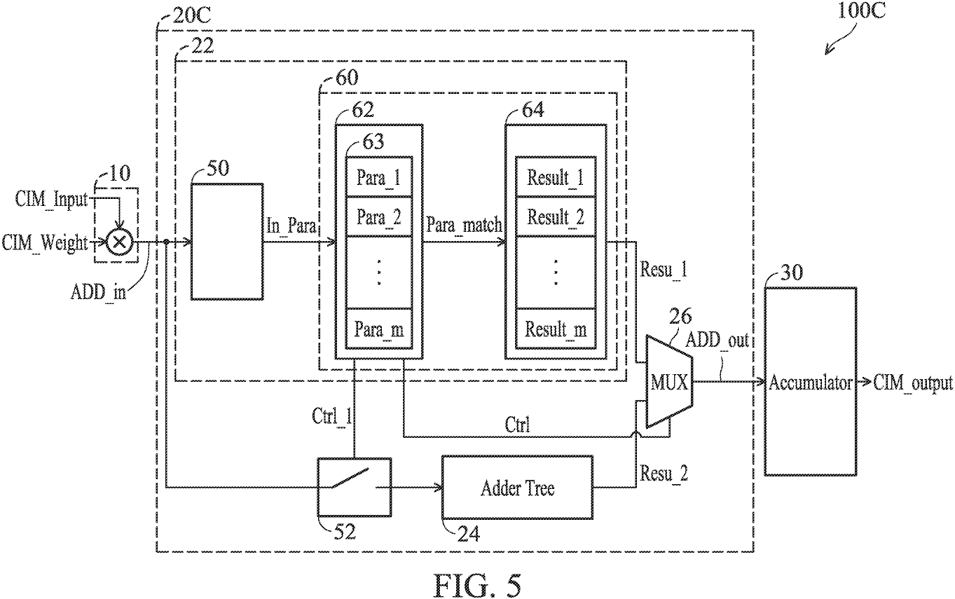

FIG. 5 shows a CIM device 100C, in accordance with some embodiments of the disclosure. The CIM device 100C may be an IC. The CIM device 100C includes the memory 10, an addition circuit 20C and the accumulator 30. The circuit configuration of the CIM device 100C of FIG. 5 is similar with the circuit configuration of the CIM device 100B of FIG. 4. The different between the CIM device 100C of FIG. 5 and the CIM device 100B of FIG. 4 is that the addition circuit 20C further includes the selection unit 26. As described above, in response to the control signal Ctrl, the selection unit 26 is configured to selectively provide the pre-computation result Resu_1 or the computed result Resu_2 as the adder output ADD_out. In some embodiments, the selection unit 26 may be a multiplexer (MUX).

In the addition circuit 20C, if the input parameter In Para is identified according to the parameter table 63, e.g., the input parameter In_Para is equal to one of the pre-stored parameters Para_1 through Para_m in the parameter table 63, the parameter comparing circuit 62 is configured to provide the control signal Ctrl to the selection unit 26. Thus, the pre-computation result Resu_1 is provided to the accumulator 30 as the adder output ADD_out through the selection unit 26. Conversely, if the input parameter In_Para is not identified, e.g., the input parameter In Para is different from the pre-stored parameters Para_1 through Para_m in the parameter table 63, the parameter comparing circuit 62 is configured to provide the control signal Ctrl to the selection unit 26. Thus, the computed result Resu_2 is provided to the accumulator 30 as the adder output ADD_out through the selection unit 26.

In the CIM device 100C, by using the selection unit 26, the intermediate state produced by the adder tree 24 performing the addition operation does not interfere with the pre-computation result Resu_1 when the switching unit 52 is not turned off by the control signal Ctrl_1.

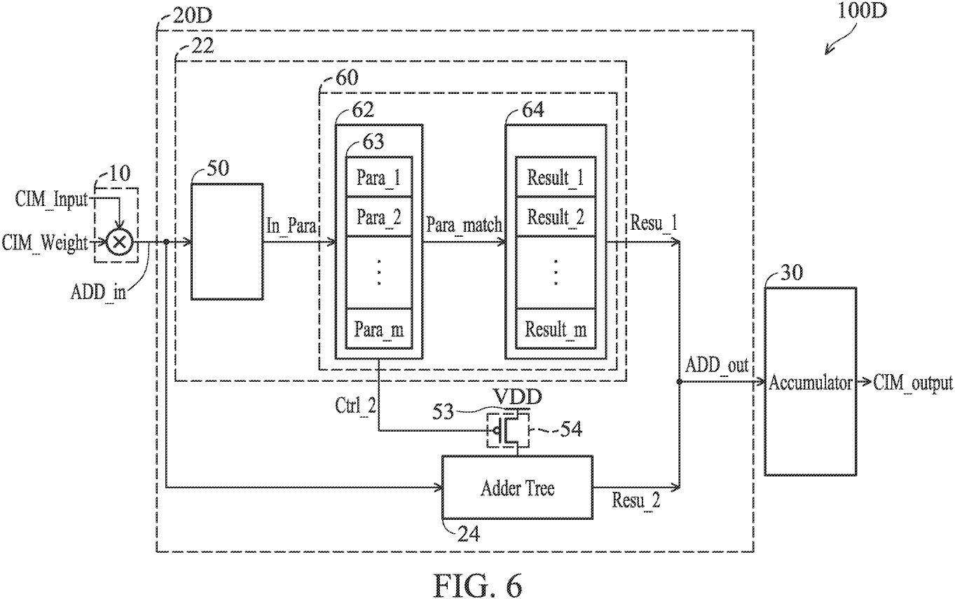

FIG. 6 shows a CIM device 100D, in accordance with some embodiments of the disclosure. The CIM device 100D may be an IC. The CIM device 100D includes the memory 10, an addition circuit 20D and the accumulator 30. The addition circuit 20D includes the pre-computation circuit 22, a switch unit 54 and the adder tree 24. The switch unit 54 is coupled between the adder tree 24 and a power terminal 53. In some embodiments, the switch unit 54 is a header unit formed by a PMOS transistor or a transmission gate. As described above, the pre-computation circuit 22 is capable of providing a fast path for the addition operation of the adder input ADD_in. Furthermore, when the switching unit 54 is turned on by the control signal Ctrl_2, a supply voltage VDD from the power terminal 53 is applied to the adder tree 24, and the adder tree 24 is capable of providing a normal path for the addition operation of the adder input ADD _in.

In some embodiments, the whole adders 40 of the adder tree 24 in FIG. 3 are coupled to the power terminal 53 through the switching unit 54. Therefore, when the switching unit 54 is turned off by the control signal Ctrl_2, the adders 40 of adder tree 24 are powered off. Conversely, when the switching unit 54 is turned on by the control signal Ctrl_2, the adders 40 of adder tree 24 are powered by the supply voltage VDD.

In some embodiments, the switching unit 54 is initially turned on by the control signal Ctrl_2. If the input parameter In Para is identified according to the parameter table 63, e.g., the input parameter In_Para is equal to one of the pre-stored parameters Para_1 through Para_m in the parameter table 63, the parameter comparing circuit 62 is configured to provide the control signal Ctrl_2 to turn off the switching unit 54. Thus, no supply voltage VDD is supplied to the adder tree 24. Therefore, no computed result Resu_2 is provided by the adder tree 24, and the addition circuit 20D is configured to provide the pre-computation result Resu_1 as the adder output ADD_out. In such embodiment, the power consumption of the CIM device 100D is decreased because the switching unit 54 is turned off and the adder tree 24 is powered down in the normal path. Conversely, if the input parameter In_Para is not identified, e.g., the input parameter In_Para is different from the pre-stored parameters Para_1 through Para_m in the parameter table 63, the parameter comparing circuit 62 does not provide the match signal Para_match to the storage device 64. Simultaneously, the parameter comparing circuit 62 is configured to provide the control signal Ctrl_2 to continue to turn on the switching unit 54. Thus, the adder tree 24 is configured to perform the addition operation on the adder input ADD_in to obtain the computed result Resu_2, and then the addition circuit 20D is configured to provide the computed result Resu_2 as the adder output ADD_out.

In some embodiments, the switching unit 54 is initially turned off by the control signal Ctrl_2. If the input parameter In Para is identified according to the parameter table 63, e.g., the input parameter In_Para is equal to one of the pre-stored parameters Para_1 through Para_m in the parameter table 63, the parameter comparing circuit 62 is configured to provide the control signal Ctrl_2 to continue to turn off the switching unit 54. Thus, the adder tree 24 is powered down, and the addition circuit 20D is configured to provide the pre-computation result Resu_1 as the adder output ADD_out. In such embodiment, the power consumption of the CIM device 100D is decreased because the switching unit 54 is turned off and the supply voltage VDD cannot be supplied to the adder tree 24. Conversely, if the input parameter In Para is not identified, e.g., the input parameter In_Para is different from the pre-stored parameters Para_1 through Para_m in the parameter table 63, the parameter comparing circuit 62 does not provide the match signal Para_match to the storage device 64. Simultaneously, the parameter comparing circuit 62 is configured to provide the control signal Ctrl_2 to turn on the switching unit 54. Thus, the supply voltage VDD is provided to the adder tree 24 through the switching unit 54. Next, the adder tree 24 is configured to perform the addition operation on the adder input ADD_in to obtain the computed result Resu_2, and then the addition circuit 20D is configured to provide the computed result Resu_2 as the adder output ADD_out.

In some embodiments, the addition circuit 20D further includes the selection unit 26. As described above, the selection unit 26 is configured to selectively provide the pre-computation result Resu_1 or the computed result Resu_2 as the adder output ADD_out. By using the selection unit 26, the intermediate state produced by the adder tree 24 performing the addition operation does not interfere with the pre-computation result Resu_1 when the switching unit 54 is not turned off by the control signal Ctrl_2.

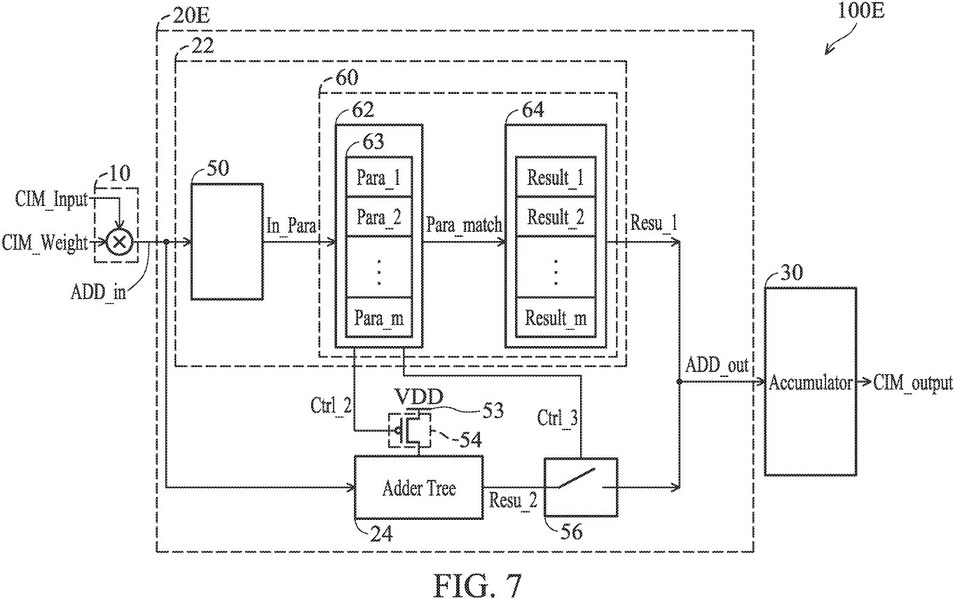

FIG. 7 shows a CIM device 100E, in accordance with some embodiments of the disclosure. The CIM device 100E may be an IC. The CIM device 100E includes the memory 10, an addition circuit 20E and the accumulator 30. The circuit configuration of the CIM device 100E of FIG. 7 is similar with the circuit configuration of the CIM device 100D of FIG. 6. The different between the CIM device 100E of FIG. 7 and the CIM device 100BD of FIG. 6 is that the addition circuit 20E further includes the switching unit 56. The switching unit 56 is coupled between the adder tree 24 and the accumulator 30. When the switching unit 56 is turned on by the control signal Ctrl_3, the adder tree 24 is capable of providing the computed result Resu_2 as the adder output ADD_out.

In some embodiments, the switching unit 56 is initially turned on by the control signal Ctrl_3. If the input parameter In Para is identified according to the parameter table 63, e.g., the input parameter In_Para is equal to one of the pre-stored parameters Para_1 through Para_m in the parameter table 63, the parameter comparing circuit 62 is configured to provide the control signal Ctrl_3 to turn off the switching unit 56. Thus, no computed result Resu_2 is provided to the accumulator 30, and the addition circuit 20E is configured to provide the pre-computation result Resu_1 as the adder output ADD_out. Conversely, if the input parameter In_Para is not identified, e.g., the input parameter In_Para is different from the pre-stored parameters Para_1 through Para_m in the parameter table 63, the parameter comparing circuit 62 does not provide the match signal Para_match to the storage device 64. Simultaneously, the parameter comparing circuit 62 is configured to provide the control signal Ctrl_3 to continue to turn on the switching unit 56. Thus, the adder tree 24 is configured to provide the computed result Resu_2 as the adder output ADD_out.

In some embodiments, the switching unit 56 is initially turned off by the control signal Ctrl_3. If the input parameter In Para is identified according to the parameter table 63, e.g., the input parameter In_Para is equal to one of the pre-stored parameters Para_1 through Para_m in the parameter table 63, the parameter comparing circuit 62 is configured to provide the control signal Ctrl_3 to continue to turn off the switching unit 56. Thus, the addition circuit 20E is configured to provide the pre-computation result Resu_1 as the adder output ADD_out. Conversely, if the input parameter In_Para is not identified, e.g., the input parameter In_Para is different from the pre-stored parameters Para_1 through Para_m in the parameter table 63, the parameter comparing circuit 62 does not provide the match signal Para_match to the storage device 64. Simultaneously, the parameter comparing circuit 62 is configured to provide the control signal Ctrl_3 to turn on the switching unit 56. Thus, the addition circuit 20B is configured to provide the computed result Resu_2 as the adder output ADD_out.

In the CIM device 100E, by using the switching unit 56, the intermediate state produced by the adder tree 24 performing the addition operation does not interfere with the pre-computation result Resu_1 when the switching unit 54 is not turned off by the control signal Ctrl_2.

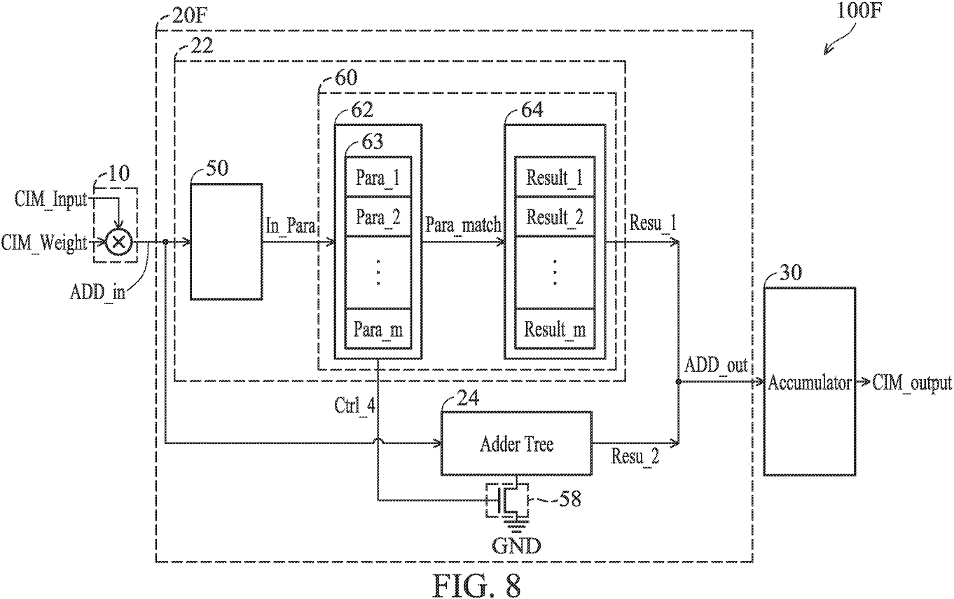

FIG. 8 shows a CIM device 100F, in accordance with some embodiments of the disclosure. The CIM device 100F may be an IC. The CIM device 100F includes the memory 10, an addition circuit 20F and the accumulator 30. The addition circuit 20F includes the pre-computation circuit 22, a switch unit 58 and the adder tree 24. The switch unit 58 is coupled between the adder tree 24 and a ground terminal GND. In some embodiments, the switch unit 58 is a footer unit formed by an NMOS transistor or a transmission gate. When the switching unit 58 is turned on by the control signal Ctrl_4, the adder tree 24 is capable of providing a normal path for the addition operation of the adder input ADD_in.

In some embodiments, the whole adders 40 of the adder tree 24 in FIG. 3 are coupled to the ground terminal GND through the switching unit 58. Therefore, when the switching unit 58 is turned off by the control signal Ctrl_4, the sources of NMOS transistors in the adders 40 of adder tree 24 are not connected to the ground terminal GND. Conversely, when the switching unit 58 is turned on by the control signal Ctrl_4, the sources of NMOS transistors in the adders 40 of adder tree 24 are connected to the ground terminal GND through the switching unit 58.

In some embodiments, the switching unit 58 is initially turned on by the control signal Ctrl_4. If the input parameter In_Para is identified according to the parameter table 63, e.g., the input parameter In_Para is equal to one of the pre-stored parameters Para_1 through Para_m in the parameter table 63, the parameter comparing circuit 62 is configured to provide the control signal Ctrl_4 to turn off the switching unit 58. Therefore, no computed result Resu_2 is provided by the adder tree 24, and the addition circuit 20F is configured to provide the pre-computation result Resu_1 as the adder output ADD_out. In such embodiment, the power consumption of the CIM device 100F is decreased because the switching unit 58 is turned off and the adder tree 24 is powered down. Conversely, if the input parameter In_Para is not identified, e.g., the input parameter In_Para is different from the pre-stored parameters Para_1 through Para_m in the parameter table 63, the parameter comparing circuit 62 does not provide the match signal Para_match to the storage device 64. Simultaneously, the parameter comparing circuit 62 is configured to provide the control signal Ctrl_4 to continue to turn on the switching unit 58. Thus, the adder tree 24 is configured to perform the addition operation on the adder input ADD_in to obtain the computed result Resu_2, and then the addition circuit 20F is configured to provide the computed result Resu_2 as the adder output ADD_out.

In some embodiments, the switching unit 58 is initially turned off by the control signal Ctrl_4. If the input parameter In_Para is identified according to the parameter table 63, e.g., the input parameter In_Para is equal to one of the pre-stored parameters Para_1 through Para_m in the parameter table 63, the parameter comparing circuit 62 is configured to provide the control signal Ctrl_4 to continue to turn off the switching unit 58. Thus, the adder tree 24 is powered down, and the addition circuit 20F is configured to provide the pre-computation result Resu_1 as the adder output ADD_out. In such embodiment, the power consumption of the CIM device 100F is decreased because the switching unit 58 is turned off and the adder tree 24 cannot operate. Conversely, if the input parameter In_Para is not identified, e.g., the input parameter In_Para is different from the pre-stored parameters Para_1 through Para_m in the parameter table 63, the parameter comparing circuit 62 does not provide the match signal Para_match to the storage device 64. Simultaneously, the parameter comparing circuit 62 is configured to provide the control signal Ctrl_4 to turn on the switching unit 58. Thus, the adder tree 24 is configured to perform the addition operation on the adder input ADD_in to obtain the computed result Resu_2, and then the addition circuit 20F is configured to provide the computed result Resu_2 as the adder output ADD_out.

In some embodiments, the addition circuit 20D further includes the selection unit 26 of FIG. 5 or the switching unit 56 of FIG. 7. As described above, by using the selection unit 26 or the switching unit 56, the intermediate state produced by the adder tree 24 performing the addition operation does not interfere with the pre-computation result Resu_1 when the switching unit 58 is not turned off by the control signal Ctrl_4.

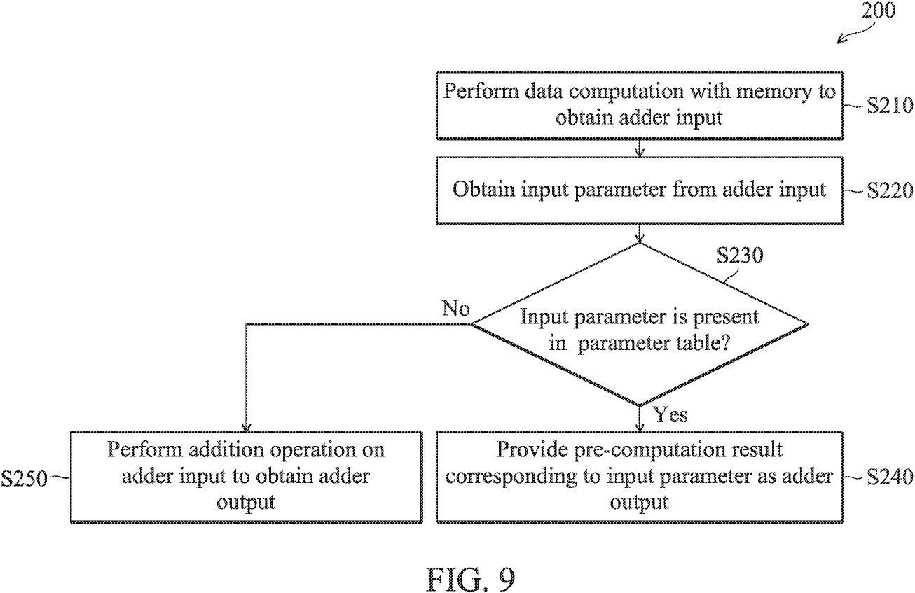

FIG. 9 shows a computing method 200, in accordance with some embodiments of the disclosure. The computing method 200 is performed by a CIM device (e.g., the CIM devices 100A through 100F). Furthermore, the memory includes a plurality of memory cells arranged in rows and columns of a memory array.

In operation S210, the memory is configured to perform data computation so as to obtain an adder input ADD_in. For example, each memory cell is configured to multiply a respective bit of input data CIM_Input by a respective bit of a weight CIM_Weight to obtain a respective bit of adder input ADD_in.

In operation S220, an input parameter In_Para is obtained (or extracted) from the adder input ADD_in. In some embodiments, the bit number of “1” in the adder input ADD_in is counted to obtain the input parameter In_Para.In some embodiments, a specific function (e.g., the parity function or the remainder function) is performed on the adder input ADD_in to obtain the input parameter In_Para.

In operation S230, it is determined whether the input parameter In_Para is present in a parameter table. As described above, the parameter table records the worst-case and common-case input parameters for the adder input ADD_in.

In operation S240, if the input parameter In_Para is present in the parameter table, e.g., the input parameter In_Para is equal to one of the pre-stored parameters Para_1 through Para_m in the parameter table 63, a pre-computation result Resu_1 corresponding to the input parameter In_Para is provided as the adder output ADD_out for subsequent calculations in the accumulator 30. Simultaneously, the adder tree is bypassed (or disabled) to decrease power consumption.

In operation S250, if the input parameter In_Para is not present in the parameter table, e.g., the input parameter In_Para is different from the pre-stored parameters Para_1 through Para_m in the parameter table 63, the adder tree is configured to perform addition operations on the adder input ADD_in to obtain the computed result Resu_2.

Embodiments of CIM devices and computing method thereof are provided. In the CIM device, the pre-computation circuit 22 is provided for the pre-computation of specific case (e.g., common cases or worst cases) without the adder tree 24 (e.g., disabling the adder tree 24). Since power consumption of the adder tree 24 is decreased, the energy efficiency (e.g., Tera-Operations/Second/Watt (TOPS/W)) can also improve obviously.

In some embodiments, a compute-in memory (CIM) device is provided. The CIM device includes a memory, an addition circuit, and an accumulator. The memory includes a plurality of memory cells, and each of the memory cells is configured to multiply a respective bit of input data by a respective bit of a weight to obtain a respective bit of an adder input. The addition circuit is configured to receive the adder input to provide an adder output. The addition circuit includes a pre-computation circuit and an adder tree. The pre-computation circuit includes a parameter extractor and a parameter identification circuit. The parameter extractor is configured to extract an input parameter from the adder input. The parameter identification circuit is configured to provide a pre-computation result corresponding to the input parameter as the adder output when determining that the input parameter is present in a parameter table, and provide a control signal when determining that the input parameter is not present in the parameter table. The adder tree is configured to provide the adder output according to the adder input in response to the control signal. The accumulator is configured to perform an accumulative adding calculation on the adder output to provide accumulated output data.

In some embodiments, a compute-in memory (CIM) device is provided. The CIM device includes a memory array, an addition circuit and an accumulator. The memory array is configured to multiply input data by a weight to obtain an adder input, and the bit number of the weight is different from the bit number of the input data. The addition circuit is configured to receive the adder input to provide an adder output. The addition circuit includes a pre-computation circuit and an adder tree. The pre-computation circuit is configured to store a plurality of pre-stored parameters, and provide a pre-computation result corresponding to an input parameter of the adder input as the adder output when the input parameter is equal to one of the pre-stored parameters. The adder tree is configured to provide the adder output according to the adder input when the input parameter is different from the pre-stored parameters. The accumulator is configured to perform an accumulative adding calculation on the adder output to provide accumulated output data.

In some embodiments, a computing method is provided. Data computation is performed with a memory to obtain an adder input. An input parameter is obtained from the adder input. It is determined whether the input parameter is present in a parameter table. A pre-computation result corresponding to the input parameter is provided as an adder output when determining that the input parameter is present in the parameter table. An addition operation is performed on the adder input with an adder tree to obtain the adder output when determining that the input parameter is not present in the parameter table.

The foregoing outlines nodes of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A compute-in memory (CIM) device, comprising:
a memory comprising a plurality of memory cells, wherein each of the memory cells is configured to multiply a respective bit of input data by a respective bit of a weight to obtain a respective bit of an adder input;
an addition circuit configured to receive the adder input to provide an adder output, and comprising:
a pre-computation circuit, comprising:
a parameter extractor configured to extract an input parameter from the adder input; and
a parameter identification circuit configured to provide a pre-computation result corresponding to the input parameter as the adder output when determining that the input parameter is present in a parameter table, and provide a control signal when determining that the input parameter is not present in the parameter table; and
an adder tree configured to provide the adder output according to the adder input in response to the control signal; and
an accumulator configured to perform an accumulative adding calculation on the adder output to provide accumulated output data.

2. The CIM device as claimed in claim 1, wherein the parameter identification circuit comprises:
a parameter comparing circuit configured to compare the input parameter with a plurality of pre-stored parameters in the parameter table; and
a storage device configured to store a plurality of pre-stored results, wherein each of the pre-stored results corresponds to a respective pre-stored parameter,
wherein when the input parameter is equal to one of the pre-stored parameters in the parameter table, the parameter identification circuit is configured to determine that the input parameter is present in the parameter table, and provide the pre-stored result corresponding to the one of the pre-stored parameters as the pre-computation result.

3. The CIM device as claimed in claim 1, further comprising:
a switching unit coupled between the memory and the adder tree,
wherein when the input parameter is not present in the parameter table, the parameter identification circuit is configured to provide the control signal to turn on the switching unit,
wherein when the input parameter is present in the parameter table, the parameter identification circuit is configured to provide the control signal to turn off the switching unit.

4. The CIM device as claimed in claim 1, wherein the adder tree comprises a plurality of adders interconnected in a tree-like configuration.

5. The CIM device as claimed in claim 4, further comprising:
a switching unit coupled between a power supply and the adders of the adder tree,
wherein when the input parameter is not present in the parameter table, the parameter identification circuit is configured to provide the control signal to turn on the switching unit,
wherein when the input parameter is present in the parameter table, the parameter identification circuit is configured to provide the control signal to turn off the switching unit.

6. The CIM device as claimed in claim 4, further comprising:
a switching unit coupled between a ground and the adders of the adder tree,
wherein when the input parameter is not present in the parameter table, the parameter identification circuit is configured to provide the control signal to turn on the switching unit,
wherein when the input parameter is present in the parameter table, the parameter identification circuit is configured to provide the control signal to turn off the switching unit.

7. The CIM device as claimed in claim 1, further comprising:
a switching unit coupled between the adder tree and the accumulator,
wherein when the input parameter is not present in the parameter table, the parameter identification circuit is configured to provide the control signal to turn on the switching unit,
wherein when the input parameter is present in the parameter table, the parameter identification circuit is configured to provide the control signal to turn off the switching unit.

8. The CIM device as claimed in claim 1, wherein the parameter extractor is configured to count the number of 1 in binary representation of the adder input to obtain the input parameter.

9. The CIM device as claimed in claim 1, wherein the parameter extractor is configured to perform a parity function or a remainder function on the adder input to obtain the input parameter.

10. A compute-in memory (CIM) device, comprising:
a memory array configured to multiply input data by a weight to obtain an adder input, wherein bit number of the weight is different from bit number of the input data;
an addition circuit configured to receive the adder input to provide an adder output, and comprising:
a pre-computation circuit configured to store a plurality of pre-stored parameters, and provide a pre-computation result corresponding to an input parameter of the adder input as the adder output when the input parameter is equal to one of the pre-stored parameters; and
an adder tree configured to provide the adder output according to the adder input when the input parameter is different from the pre-stored parameters; and
an accumulator configured to perform an accumulative adding calculation on the adder output to provide accumulated output data.

11. The CIM device as claimed in claim 10, wherein the pre-computation circuit comprises:
a parameter extractor configured to extract the input parameter from the adder input;
a parameter comparing circuit configured to compare the input parameter with the pre-stored parameters; and
a storage device configured to store a plurality of pre-stored results, wherein each of the pre-stored results corresponds to a respective pre-stored parameter,
wherein when the input parameter is equal to the one of the pre-stored parameters in the parameter table, the pre-computation circuit is configured to provide the pre-stored result corresponding to the one of the pre-stored parameters as the pre-computation result.

12. The CIM device as claimed in claim 10, further comprising:
a switching unit coupled between the memory array and the adder tree,
wherein when the input parameter is different from the pre-stored parameters, the pre-computation circuit is configured to turn on the switching unit,
wherein when the input parameter is equal to the one of the pre-stored parameters, the pre-computation circuit is configured to turn off the switching unit.

13. The CIM device as claimed in claim 10, wherein the adder tree comprises a plurality of adders interconnected in a tree-like configuration.

14. The CIM device as claimed in claim 13, further comprising:
a switching unit coupled between a power supply and the adders of the adder tree,
wherein when the input parameter is different from the pre-stored parameters, the pre-computation circuit is configured to turn on the switching unit,
wherein when the input parameter is equal to the one of the pre-stored parameters, the pre-computation circuit is configured to turn off the switching unit.

15. The CIM device as claimed in claim 13, further comprising:
a switching unit coupled between a ground and the adders of the adder tree,
wherein when the input parameter is different from the pre-stored parameters, the pre-computation circuit is configured to turn on the switching unit,
wherein when the input parameter is equal to the one of the pre-stored parameters, the pre-computation circuit is configured to turn off the switching unit.

16. The CIM device as claimed in claim 10, further comprising:
a switching unit coupled between the adder tree and the accumulator,
wherein when the input parameter is different from the pre-stored parameters, the pre-computation circuit is configured to turn on the switching unit,
wherein when the input parameter is equal to the one of the pre-stored parameters, the pre-computation circuit is configured to turn off the switching unit.

17. A computing method, comprising:
performing data computation with a memory to obtain an adder input;
obtaining an input parameter from the adder input;
determining whether the input parameter is present in a parameter table;
providing a pre-computation result corresponding to the input parameter as an adder output when determining that the input parameter is present in the parameter table; and
performing an addition operation on the adder input with an adder tree to obtain the adder output when determining that the input parameter is not present in the parameter table.

18. The computing method as claimed in claim 17, wherein the memory comprises a plurality of memory cells, and each of the memory cells is configured to multiply a respective bit of input data by a respective bit of a weight to obtain a respective bit of the adder input.

19. The computing method as claimed in claim 17, wherein determining whether the input parameter is present in the parameter table further comprises:
comparing the input parameter with a plurality of pre-stored parameters in the parameter table;
determining that the input parameter is present in the parameter table when the input parameter is equal to one of the pre-stored parameters in the parameter table; and
determining that the input parameter is not present in the parameter table when the input parameter is different from the pre-stored parameters in the parameter table.

20. The computing method as claimed in claim 17, further comprising:
disabling the adder tree when determining that the input parameter is present in the parameter table.
